(19) United States
(12) Patent Application Publication
(10) Pub. No.: US 2007/0054493 A1
(43) Pub. Date: Mar. 8, 2007

(54) Methods of forming patterns using phase change material and methods for removing the same

(75) Inventor: Dong-seok Nam, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/509,729

(22) Filed: Aug. 25, 2006

(30) Foreign Application Priority Data
Sep. 5, 2005 (KR) 10-2005-0082447

(51) Int. Cl. C23F 1/00; H01L 21/302

(52) U.S. Cl. 438/689; 216/41

(57) ABSTRACT

In a method of forming patterns using a phase change material layer a phase change material layer may be formed, and selectively phase-changed along a pattern using an exposure beam or other heat source. A phase change material layer pattern may be formed by selectively removing phase-changed portions using a solution that dissolves only the phase-changed portion.

### PRIORITY STATEMENT

This application claims priority under 35 U.S.C. § 119 to Korean Patent Application No. 10-2005-0082447, filed on Sep. 5, 2005, in the Korean Intellectual Property Office (KIPO), the entire contents of which are incorporated herein by reference.

### BACKGROUND OF THE INVENTION

1. Field of the Invention

Example embodiments of the present invention relate to methods of fabricating semiconductor devices, for example, methods of forming patterns of semiconductor devices.

2. Description of the Related Art

With increasing integration, semiconductor devices may require smaller patterns. If a semiconductor device has a fine pattern formed using an exposure beam having a shorter wavelength, a photoresist must be thinner, otherwise the depth of focus (DOF) may become insufficient. Reducing the size of a photoresist pattern while keeping the same thickness may increase the aspect ratio, and the photoresist pattern may collapse. The photoresist having a smaller thickness may not provide a sufficient layer pattern due to an insufficient amount of the photoresist in etching the layer, and thus, a bilayer photoresist process may be used.

In the bilayer photoresist process, an upper photoresist layer may be formed on a lower photoresist layer. The upper photoresist layer may be a photosensitive material containing, for example, silicon. The upper photoresist layer may be patterned by exposure and development while the lower photoresist layer may be patterned using, for example, oxygen (O₂) plasma etching with the upper photoresist pattern serving as a mask.

In the oxygen plasma etching process, silicon oxide may be formed by silylation in the pattern of the upper photoresist layer containing silicon, thereby increasing etching resistance.

The upper photoresist layer pattern may be formed to a thickness of about 100 nm and a polymer component of the upper photoresist layer pattern may be removed by the silylation process, resulting in a silicon oxide (SiO₂) pattern having a thickness of about 20 nm to about 30 nm. Thus, the upper photoresist layer should be formed over a certain thickness and should include silicon, allowing the silicon oxide to be formed by silylation.

During exposure, the thickness of the upper photoresist layer may exceed the reduced depth of focus which appears at higher numerical apertures (NA). Further, the silicon oxide created by the silylation of the upper photoresist layer, but not completely removed, may be a source of particles. Further still, because the sensitivity of the photoresist varies with the wavelength of the exposure beam, the use of a short wavelength exposure beam may require a photoresist that corresponds to that wavelength.

### SUMMARY OF THE INVENTION

Example embodiments of the present invention provide methods of forming patterns capable of providing a margin of depth of focus (DOF) upon exposure, a rework process for a method of forming patterns and/or a method of forming patterns, wherein photolithography may not be used.

At least some example embodiments of the present invention may solve drawbacks caused by increased aspect ratios of fine photoresist patterns

According to an example embodiment of the present invention, a phase change material layer may be formed on a base. The phase change material layer may be selectively phase-changed, and a phase changed portion may be selectively removed to form a phase change material layer pattern. The phase change may be from amorphous to crystalline. The selective phase change may be made by heating, applying a laser beam, electric current or an electron beam, or using an exposure apparatus. The phase change material layer may be formed of, for example, GeSbTe.

According to another example embodiment of the present invention a first material layer may be formed on a base. A phase change material layer may be formed on the first material layer. The phase change material layer may be selectively phase-changed, and a phase-changed portion may be selectively removed to form a phase change material layer pattern. A first material layer pattern may be formed by etching the first material layer using the phase change material layer pattern as a mask.

According to another example embodiment of the present invention, an entire phase change material layer or phase change material layer pattern formed on a base may be phase-changed and removed.

The selective removing of the phase-changed portion may be made by using a metal hydroxide solution, and the metal hydroxide solution may include a sodium hydroxide (NaOH) solution. The selective removing of the phase-changed portion may also be made by using a basic solution.

Example embodiments of the present invention may further include forming a pattern on the base by etching the base using the phase change material layer pattern as a mask.

The first material layer may be a photoresist layer or a hard mask layer. The phase change may be from amorphous to crystalline. The selective phase change may be made by heating, applying a laser beam, electric current or an electron beam, or using an exposure apparatus. The phase change material layer may be formed of GeSbTe.

The phase-changing of the entire phase change material layer or phase change material layer pattern may be made by heating or applying a laser beam, electric current or an electron beam to the base having the phase change material layer or phase change material layer pattern.

The removing of the entire phase-changed phase change material layer or phase change material layer pattern may be made by using a metal hydroxide solution, and the metal hydroxide solution may include a sodium hydroxide (NaOH) solution. The selective removing of the phase-changed portion may also be made by using a basic solution.

### BRIEF DESCRIPTION OF THE DRAWINGS

The present invention will become more apparent by describing in detail the example embodiments as shown in the attached drawings in which:

FIG. 1 is a cross-sectional view illustrating a photoresist structure having a phase change material layer according to an example embodiment of the present invention;

FIG. 2A is a SEM photograph illustrating a plan view of the structure of FIG. 1 exposed by an exposure apparatus but not developed;

FIG. 2B is a SEM photograph illustrating a plan view of the structure of FIG. 1 exposed and developed by a NaOH solution;

FIG. 3 is a flowchart illustrating a process of forming a photoresist pattern having a phase change material layer according to another example embodiment of the present invention; and

FIGS. 4A and 4B are flowcharts illustrating a process of removing a phase change material layer or a phase change material layer pattern according to another example embodiment of the present invention.

### DETAILED DESCRIPTION OF EXAMPLE EMBODIMENTS OF THE PRESENT INVENTION

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

A “base” as referred may be a quartz substrate such as a mask or reticle, a semiconductor substrate, a substrate or the like on which a layer to be etched may be formed. Example embodiments of the present invention present invention are applicable to any base on which a material film pattern, a photoresist pattern and the like may be formed. They are collectively referred to as a base.

GeSbTe is a material of which the phase may be changed by heating. The heating may change amorphous GeSbTe to crystalline GeSbTe. Because amorphous GeSbTe and crystalline GeSbTe have different optical and electrical properties and exhibit a higher speed phase change between the two phases, they may be applied to a phase change optical recording medium and a phase change memory device. In the phase change optical recording medium, data may be read, written and/or erased by phase changing the GeSbTe with a laser beam to form a pattern. In the phase change memory device, data may be stored by passing a current through a GeSbTe pattern to change the phase.

GeSbTe shows varying solubility in a metal hydroxide (MOH, where M is an alkali metal) solution depending on its phase. Amorphous GeSbTe is not soluble in the metal hydroxide solution, while the crystalline GeSbTe is more easily soluble in the metal hydroxide solution. The selective removing of the phase-changed portion may also be made by using a basic solution.

In example embodiments of the present invention, the phase change and variable solubility properties of GeSbTe may be used to form a pattern of a semiconductor device.

According to an example embodiment of the present invention, an amorphous GeSbTe layer may be formed on a base and selectively phase changed to crystalline in order to form a pattern of the GeSbTe layer. A device that may heat the GeSbTe layer along the pattern may be used. The GeSbTe layer may be selectively phase-changed by applying a laser beam, current, an electron beam or the like to heat the GeSbTe layer along the pattern. Alternatively, the GeSbTe layer may be selectively phase-changed using an exposure apparatus used in a photolithograpy process. Once the GeSbTe layer has been divided into crystalline portions and amorphous portions by selective phase change, it may be processed in a sodium hydroxide solution to remove the crystalline portion and leave a GeSbTe layer pattern. According to at least some example embodiments of the present invention, it may be possible to directly transfer a pattern to the GeSbTe layer without performing a separate etching process that uses a photoresist pattern.

According to another example embodiment of the present invention, the GeSbTe pattern formed by the method according to the above-described example embodiment of the present invention may be used as a mask to etch a layer to be etched. An etched layer pattern may be formed using the GeSbTe pattern formed by the phase change as a mask, instead of a photoresist pattern. Because the phase change property of the GeSbTe does not vary with the wavelength of the exposure beam, the GeSbTe may be used even when the wavelength of the exposure beam is changed.

In example embodiments of the present invention, the phase change material film may include chalcogenide alloys such as germanium-antimony-tellurium (Ge—Sb—Te), arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the phase change material film may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the phase change material film may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the phase change material film is described above as being formed primarily of ternary phase-change chalcogenide alloys, the chalcogenide alloy of the phase change material could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂—S₂ alloy, for example.

In an example embodiment, the phase change material film may be made of a transition metal oxide having multiple resistance states, as described above. For example, the phase change material may be made of at least one material selected from the group consisting of NiO, TiO₂, HfO, Nb₂O₅, ZnO, WO₃, and CoO or GST (Ge₂Sb₂Te₅) or PCMO(PrₓCa₁₋ₓMnO₃). The phase change material film may be a chemical compound including one or more elements selected from the group consisting of S, Se, Te, As, Sb, Ge, Sn, In and Ag.

Although the phase change material layer may be comprised of any of the above materials, for the sake of brevity example embodiments of the present invention will be described herein with respect to the phase change material layer GeSbTe. However, this description is example purposes only, and example embodiments of the present invention should not be limited thereto.

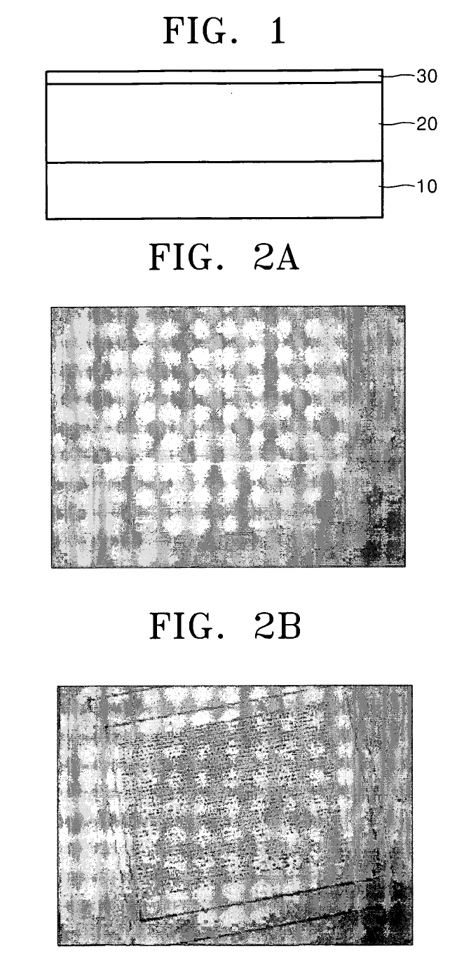

FIG. 1 is a cross-sectional view illustrating a bilayer photoresist structure having a GeSbTe layer according to an example embodiment of the present invention. As shown, a photoresist layer 20 (e.g., a silicon layer) may be formed on a layer 10 to be etched and patterned using a photoresist pattern as a mask, and a GeSbTe layer 30 may be formed on the photoresist layer 20. In at least one example embodiment of the present invention, the photoresist layer 20 may have a thickness of about 300 nm, and the GeSbTe layer 30 may have a thickness of about 30 nm.

FIG. 2A is a SEM photograph illustrating a plan view of the structure of FIG. 1 exposed by an exposure apparatus but not developed, and FIG. 2B is an SEM photograph illustrating a plan view of the structure of FIG. 1 exposed and developed by a NaOH solution. Referring to FIGS. 2A and 2B, the pattern of the GeSbTe layer 30 may be invisible before the GeSbTe layer 30 is developed, but visible after the GeSbTe layer 30 is developed by the NaOH solution.

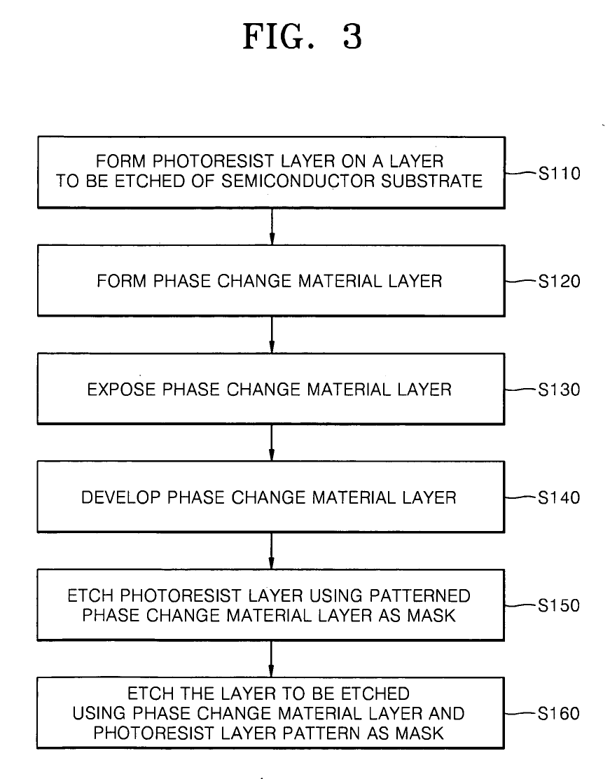

FIG. 3 is a flowchart illustrating a process of forming a bilayer photoresist pattern having a GeSbTe layer according to an example embodiment of the present invention. Referring to FIGS. 1 and 3, a photoresist layer 20 may be applied to a semiconductor substrate having a layer 10 to be etched (S110). The photoresist layer 20 may be formed to a thickness sufficient to etch the layer 10 to be etched. Because a pattern of the photoresist layer 20 may be formed to have an improved profile using a patterned GeSbTe layer 30, the photoresist layer 20 may be thinner than in the related art.

An amorphous GeSbTe layer 30 may be formed on the photoresist layer 20 (S120). The GeSbTe layer 30 may be formed to a thickness of about 30 nm or less by sputtering or the like. When a pattern of the lower photoresist layer 20 is formed using the pattern of the GeSbTe layer 30 as a mask, etching selectivity may be increased and the GeSbTe layer 30 may be thinner.

The semiconductor substrate having the GeSbTe layer 30 may be exposed by an exposure apparatus (S130). Because the exposed GeSbTe layer 30 is thinner, a sufficient margin of depth of focus (DOF), which may become an issue in the exposure process, may be obtained. For example, when a fine pattern is formed, obtaining a margin of depth of focus (DOF) may be advantageous.

A photoresist may exhibit a photochemical reaction to an exposure beam having a given or specific wavelength, while the GeSbTe may be changed from amorphous to crystalline by heat generated by beam irradiation. Accordingly, a new photoresist material photosensitive to the new wavelength of an exposure beam may be need, while the GeSbTe may not be affected by the wavelength of an exposure beam.

The photoresist layer 20 beneath the GeSbTe layer 30 may suppress and/or prevent heat transfer from occurring (e.g., easily occurring) within the GeSbTe layer 30. The crystalline areas of the GeSbTe layer 30 which were irradiated by the exposure beam may be dissolved in the developer, and the amorphous areas of the GeSbTe layer 30 which were not irradiated by the exposure beam may remain as a pattern not dissolved in the developer. If the heat in the portion irradiated by the exposure beam is transferred to portions not irradiated by the exposure beam, the crystalline and amorphous portions may indistinguishable from each other as desired. This results in a less desirable profile of an GeSbTe layer 30 pattern. The photoresist layer 20 beneath the GeSbTe layer 30 may suppress and/or prevent heat in the portion of the GeSbTe layer 30 irradiated by the exposure beam from being transferred to the portions not irradiated by the exposure beam.

The exposed GeSbTe layer 30 may be developed (e.g., etched) by a metal hydroxide (MOH, where M is a metal) solution (S140). The portion of the GeSbTe layer 30 changed to crystalline by the exposure beam may be dissolved and removed by the metal hydroxide solution to obtain the desired pattern. The metal hydroxide solution may be a NaOH solution. The selective removing of the phase-changed portion may also be made by using a basic solution.

Using the patterned GeSbTe layer 30 as a mask, the lower photoresist layer 20 may be etched to form a photoresist layer 20 pattern (S150). The layer 10 may be etched using the photoresist layer 20 pattern as a mask (S160). The GeSbTe layer 30 may have improved selectivity to the photoresist layer 20, but may be more easily etched and/or removed when the layer 10 is etched. Accordingly, the GeSbTe layer 30 may not serve as a source of particles, unlike related art upper silicon containing photoresist in a bilayer photoresist process that is not completely removed after the layer 10 is etched.

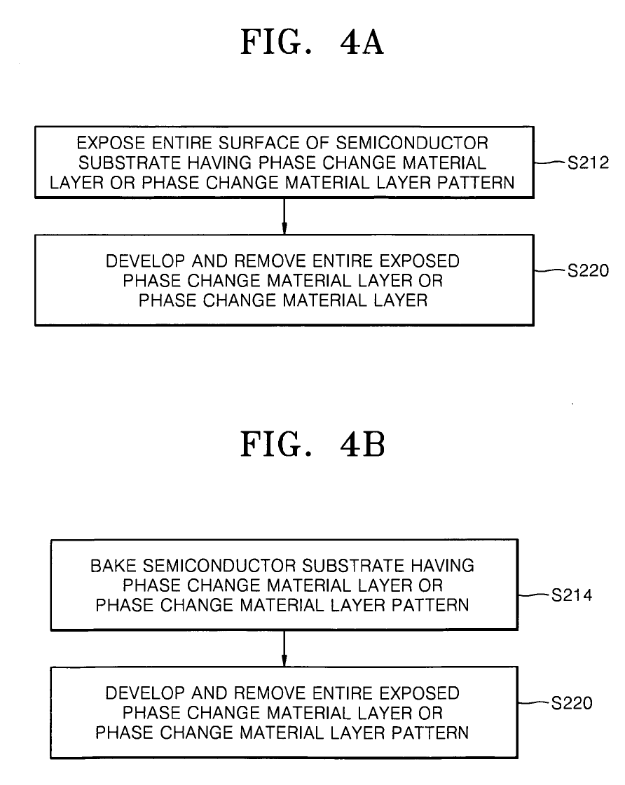

FIGS. 4A and 4B are flowcharts illustrating a process for removing a GeSbTe layer or a GeSbTe layer pattern according to another example embodiment of the present invention. In the process of forming a bilayer photoresist pattern including a GeSbTe layer, the GeSbTe layer may need to be removed, for example, when the GeSbTe layer pattern is erroneously formed. In this example, the GeSbTe layer or the GeSbTe layer pattern may be etched and removed. Alternatively, the GeSbTe layer or the GeSbTe layer pattern may be removed by exposing the entire surface of the GeSbTe layer or GeSbTe layer pattern (S212) or baking the pattern with a track apparatus (S214) to phase change the GeSbTe from the amorphous to the crystalline phase, and developing the pattern in the metal hydroxide solution (S220), as shown in FIG. 4A or 4B.

After the GeSbTe layer or the GeSbTe layer pattern is removed, the GeSbTe layer may be formed again so that the process of forming the bilayer photoresist pattern may be performed again.

According to an example embodiment of the present invention, it may be possible to form patterns (e.g., directly) in the phase change material layer using phase change, without using a photoresist pattern as a mask.

According to example embodiments of the present invention, it is also possible to obtain a margin of depth of focus (DOF) for exposure and solve drawbacks caused by increases in the aspect ratio of a fine photoresist pattern, by forming a photoresist layer pattern using a phase change material layer pattern as a mask.

In addition, according to example embodiments of the present invention, a removal and/or rework process may be performed more easily using the phase change properties of a phase change material upon the formation of patterns.

While the present invention has been particularly shown and described with reference to example embodiments thereof, it will be understood by those of ordinary skill in the art that various changes in form and detail may be made therein without departing from the spirit and scope of the present invention as defined by the following claims.

What is claimed is:

1. A method of forming a pattern, the method comprising:
forming a phase change material layer on a base;
selectively phase-changing the phase change material layer; and
selectively removing a phase-changed portion to form a phase change material layer pattern.

2. The method of claim 1, wherein the phase change is from amorphous to crystalline.

3. The method of claim 1, wherein the selective phase change is made by heating.

4. The method of claim 1, wherein the selective phase change is made by applying a laser beam.

5. The method of claim 1, wherein the selective phase change is made by using an exposure apparatus.

6. The method of claim 1, wherein the selective phase change is made by applying electric current.

7. The method of claim 1, wherein the selective phase change is made by applying an electron beam.

8. The method of claim 1, wherein the phase change material layer is formed of GeSbTe.

9. The method of claim 1, wherein the selective removing of the phase-changed portion is made by using a base solution or a metal hydroxide solution.

10. The method of claim 9, wherein the metal hydroxide solution includes a sodium hydroxide (NaOH) solution.

11. The method of claim 1, further including,
forming a pattern on the base by etching the base using the phase change material layer pattern as a mask.

12. A method of forming a pattern, the method comprising:
forming a first material layer on a base;
forming a phase change material layer on the first material layer;
selectively phase-changing the phase change material layer;
selectively removing a phase-changed portion to form a phase change material layer pattern; and
forming a first material layer pattern by etching the first material layer using the phase change material layer pattern as a mask.

13. The method of claim 12, wherein the first material layer is a photoresist layer or a hard mask layer.

14. The method of claim 12, wherein the phase change is from amorphous to crystalline.

15. The method of claim 12, wherein the selective phase change is made by heating.

16. The method of claim 12, wherein the selective phase change is made by applying a laser beam.

17. The method of claim 12, wherein the selective phase change is made by using an exposure apparatus.

18. The method of claim 12, wherein the selective phase change is made by applying an electron beam.

19. The method of claim 12, wherein the phase change material layer is formed of GeSbTe.

20. The method of claim 12, wherein the selective removing of the phase-changed portion is made by using a base solution or a metal hydroxide solution.

21. The method of claim 20, wherein the metal hydroxide solution includes a sodium hydroxide (NaOH) solution.

22. The method of claim 12, further including,
forming a pattern on the base by etching the base using the first material layer pattern as a mask.

23. A method of removing a pattern, the method comprising:
phase-changing an entire phase change material layer or phase change material layer pattern formed on a base; and
removing the entire phase-changed phase change material layer or phase change material layer pattern.

24. The method of claim 23, wherein the phase change is from amorphous to crystalline.

25. The method of claim 23, wherein the phase-changing of the entire phase change material layer or phase change material layer pattern is made by heating the base on which is formed the phase change material layer or phase change material layer pattern.

26. The method of claim 25, wherein the substrate having the phase change material layer or phase change material layer pattern is heated by baking the substrate using a baking apparatus.

27. The method of claim 23, wherein the phase-changing of the entire phase change material layer or phase change material layer pattern is made by applying a laser beam to the phase change material layer or phase change material layer pattern.

28. The method of claim 23, wherein the phase-changing of the entire phase change material layer or phase change material layer pattern is made by applying electric current to the phase change material layer or phase change material layer pattern.

29. The method of claim 23, wherein the phase-changing of the entire phase change material layer or phase change material layer pattern is made by applying an electron beam to the phase change material layer or phase change material layer pattern.

30. The method of claim 23, wherein the removing of the entire phase-changed phase change material layer or phase change material layer pattern is made by using a base solution or a metal hydroxide solution.

31. The method of claim 30, wherein the metal hydroxide solution comprises a sodium hydroxide (NaOH) solution.
